(19) United States
(12) Patent Application Publication
(10) Pub. No.: US 2004/0127011 A1
(43) Pub. Date: Jul. 1, 2004

(54) [METHOD OF ASSEMBLING PASSIVE COMPONENT]

(76) Inventors: MIN-LUNG HUANG, KAOHSIUNG (TW); YAO-TING HUANG, KAOHSIUNG (TW); CHIH-LUNG CHEN, KAOHSIUNG (TW); SHENG-TSUNG LIU, KAOHSIUNG (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/605,082

(22) Filed: Sep. 8, 2003

(30) Foreign Application Priority Data
Dec. 26, 2002 (TW) 91137426

(51) Int. Cl. H01L 21/44

(52) U.S. Cl. 438/613; 257/778

(57) ABSTRACT

A method of assembling a passive component over the active surface of a die is provided. The method shortens the signal transmission path between the die and the passive component so that electrical performance of the die after packaging is improved. In addition, the transmission path and the number of contacts on the substrate for connecting the die and the passive component are reduced. With a reduction in transmission path, size of the substrate can be reduced. Furthermore, a plurality of passive components may be assembled onto the dies of a wafer in a single operation so that there is no need to assemble individual passive component over each packaging substrate.

### CROSS REFERENCE TO RELATED APPLICATIONS

This application claims the priority benefit of Taiwan application serial no. 91137426, filed on Dec. 26, 2002.

### BACKGROUND OF INVENTION

1. Field of Invention

The present invention relates to a semiconductor packaging technique. More particularly, the present invention relates to a method of assembling a passive component on the surface of a chip.

2. Description of Related Art

As semiconductor fabrication technique continues to progress, more precise and advance electronic devices are developed due to market demand. At present, popular techniques for packaging semiconductor devices include flip-chip assembly, integrated substrate design and passive component assembly.

Semiconductor production includes providing a wafer and forming highly integrated circuit on the active surface of the wafer. The active surface further includes a plurality of bonding pads thereon. Thereafter, the wafer is diced up into a plurality of dies. The die is subsequently wire-bonded or flip-chip-bonded to a carrier such as a lead frame or a substrate. The bonding pads on the die are redistributed to the periphery or a region over the active surface of the die through transmission circuits and contact points on the carrier.

To meet the requirements in an integrated circuit (IC) design, passive components are often attached to substrate surface using surface mount technology (SMT). Hence, the passive component is able to connect electrically with the die through the patterned circuit in the substrate. Ultimately, signals produced by the die are transmitted through the patterned circuit and passive component to an external electronic device.

Note that the shorter the signal transmission path between the passive component and the die, the shorter will be the resistor-capacitor (RC) delay and hence raise over-all electrical performance of the die and the passive component. Therefore, finding the shortest signal transmission path linking a passive component to the die is an important research issue.

### SUMMARY OF INVENTION

Accordingly, one object of the present invention is to provide a method of assembling a passive component directly onto the surface of a die so that signal transmission path between the die and the passive component is shortened and corresponding transmission delay is reduced.

To achieve these and other advantages and in accordance with the purpose of the invention, as embodied and broadly described herein, the invention provides a method of assembling a passive component on a die with an active surface. The passive component has a plurality of electrodes located on the periphery and the die has a plurality of bonding pads on the active surface. The method of assembling the passive component onto the die includes the following steps. An under-bump-metallurgy (UBM) layer is formed over the bonding pads. A solder block is formed on the UBM layer. And, the terminal electrodes of the passive component are bounded to the solder block. Optionally, a patterned dielectric layer can be formed over the active surface with openings to expose the bonding pads. Optionally, a RDL can be formed to electrically couple to the bonding pads, or the UBM layer can further include the RDL.

This invention also provides chip package structure that comprises a substrate, a die, at least one under-bump-metallurgy layer, a plurality of solder blocks, a passive component, a plurality of conductive wires and a packaging plastic. The substrate has an upper surface. The die has an active surface and a back surface. The back surface of the die is in contact with the upper surface of the substrate. The active surface of the die is implemented with a plurality of boding pads thereon. The under-bump-metallurgy layer is positioned over the bonding pads. The solder blocks are placed above the under-bump-metallurgy layer. The electrodes of the passive component are bounded to the under-bump-metallurgy layer through the solder blocks. The conductive wires connect the die and the substrate together. The packaging plastic encloses the die, the passive component and the conductive wires. Optionally, a patterned dielectric layer can be included, wherein the patterned dielectric layer has openings to expose the bonding pads. Optionally, a RDL can be included to electrically couple to the bonding pads, or the UBM layer can further include the RDL.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1 and 2 are schematic sectional view showing the steps for assembling a passive component on a die according to one preferred embodiment of this invention.

FIG. 3 is a sectional view of a wire-bonded chip package having an assembled passive component therein according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

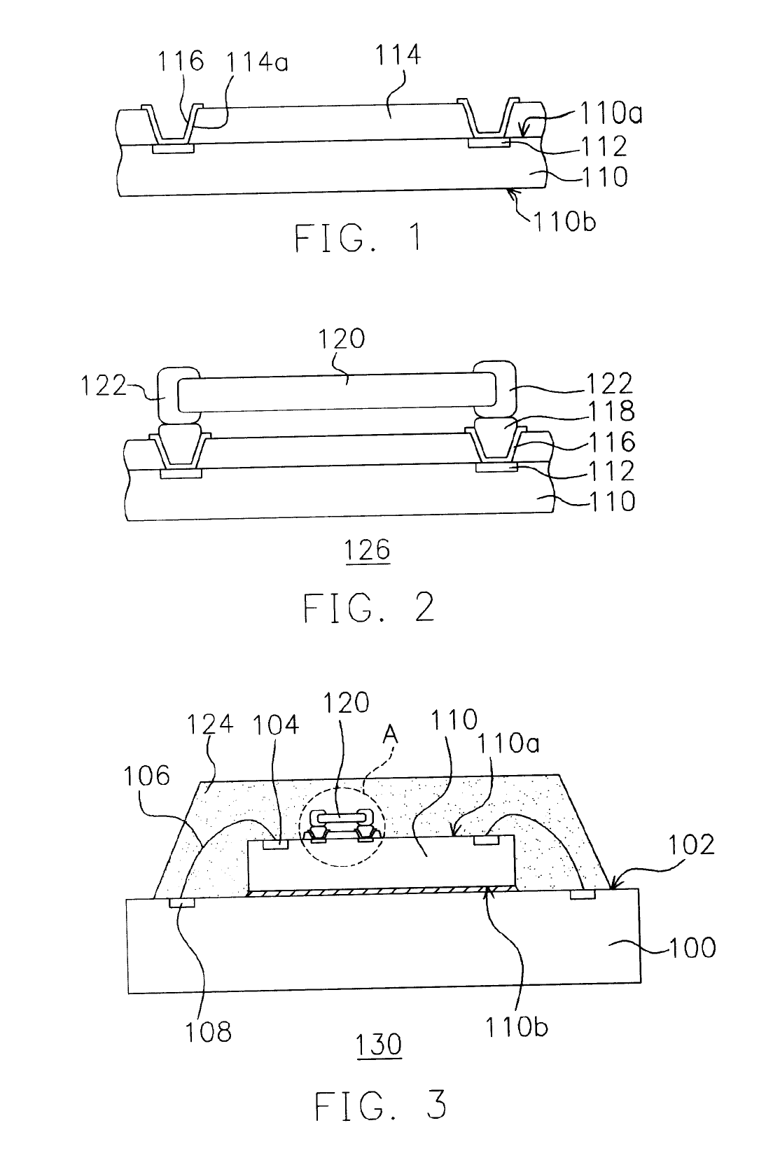

FIGS. 1 and 2 are schematic sectional view showing the steps for assembling a passive component on a die according to one preferred embodiment of this invention. As shown in FIG. 1, a patterned dielectric layer 114 is formed on the active surface 110a of a die 110. Thereafter, photolithographic and etching processes are carried out to form openings 114a in the dielectric layer 114. The openings 114a are located in positions corresponding to the bonding pads 112 on the die 110. Thus, the openings 114a expose all the bonding pads 112. Here, the dielectric layer 114 is an option of the invention as an example, and is not the required elements or processes. An under-bump-metallurgy layer 116 is formed over each bonding pad 112 by conducting electroplating, sputtering and evaporation coating. The steps for forming the under-ball-metallurgy layers 116 include forming a metallic layer over the bonding pads 112 and the dielectric layer 114 globally and then patterning (through photolithographic and etching processes) the metallic layer. The under-bump-metallurgy layer 116 can have a multi-layered structure that includes a stack of different metallic layers.

As shown in FIG. 2, solder blocks 118 are inserted into the openings 114a above the under-ball-metallurgy layer 116 by dip coating or printing. The solder blocks 118 are fabricated using a material such as lead-tin alloy. Finally, a passive component 120 is bonded to the solder blocks 118. The passive component 120, such as a resistor, a capacitor or an inductor, has two ends each having at least one electrode 122. Each electrode 122 is bonded to one of the solder blocks 118. Through the solder blocks 118, the electrode 122 and the bonding pad 112 on the die 110 are electrically connected. To increase bonding strength between the electrode 122 and the solder blocks 118, an additional reflow process is preferably conducted to obtain the consequent structure 126 as shown in FIG. 2.

FIG. 3 is a sectional view of a wire-bonded chip package having an assembled passive component therein according to one preferred embodiment of this invention. As shown in FIG. 3, the upper surface 102 of the substrate 100 has a die 110. The die 110 has an active surface 110a and a corresponding back surface 110b. The back surface 110b of the die 110 is attached to the upper surface 102 of the substrate 100. The dielectric layer constituting the substrate 100 may be fabricated from a ceramic material or an organic material. The active surface 110a of the die 110 has a plurality of bonding pads 112. The bonding pads 112 can be electrically coupled to a re-distribution layer (RDL). As can be known by the skilled artisans, the RDL is used to re-redistribute the connection terminal pads of an IC to the proper positions for easy packaging. The use of RDL is optional and the RDL can be formed by an additional layer or formed by integrating in the UBM layer, wherein the UBM also provides the function of RDL. However, the RDL does not affect the features of the invention. Then, the bonding pads 112 are fabricated using aluminum or copper, for example. It should be noted that the passive component 120 (inside circle A) and the die 110 are assembled and electrically connected together through the bonding pad 112 on the active surface 110a.

According to the passive component assembling method and wire-bonded chip package as shown in FIGS. 1, 2 and 3, passive components 120 may be assembled to the surface of a wafer before dicing the wafer into single dies. Thereafter, the dies are individually attached to a substrate 100 and enclosed to form a package as shown in FIG. 3. The process includes providing a wafer (containing many undiced dies) with a plurality of bonding pads 112 on the active surfaces 110a and then forming the dielectric layer 114, the under-bump-metallurgy layers 116 and the solder blocks 118 as described with reference to FIGS. 1 and 2. Thereafter, the electrodes 122 of the passive components 120 are bonded to the respective solder blocks 118. Hence, the active surface 110a of the wafer (with undiced die 110 thereon) has a plurality of passive components thereon. Consequently, the wafer is diced to produce single dies.

In FIG. 3, the die 110 is attached to the upper surface 102 of the substrate 100 with the bonding pad 104 on the die 110 electrically connected to the contact pad 108 on the substrate 100 through a conductive wire 106. Plastic materials 124 are injected to enclose the die 110, the passive component 120 and the conductive wires, thereby forming a wire-bonded chip package 130.

In summary, major advantages of the passive component assembling method according to this invention include: 1. A passive component is directly attached to the active surface of a die so that signal transmission path between the die and the passive component is shortened and corresponding transmission delay is reduced. 2. By attaching the passive component onto the active surface of a die directly, the number of transmission circuits and contact points in the substrate for connecting between the die and the passive component is reduced. Hence, size of the substrate can be reduced. 3. Passive components can be assembled to the active surface of a wafer in a single operation after complete fabrication of the wafer. This speeds up and simplifies the process of attaching a die to a substrate.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of assembling a passive component on a die, wherein the passive component has a plurality of terminal electrodes and the die has an active surface with a plurality of bonding pads thereon, the assembling method comprising:
forming an under-bump-metallurgy (UBM) layer over the bonding pads;
forming a solder block on the UBM layer; and
bonding the terminal electrodes of the passive component to the solder block.

2. The assembling method of claim 1, wherein the step of forming the UBM layer over the bonding pads comprises forming a re-distribution layer over the active surface coupled to the bonding pads.

3. The assembling method of claim 1, before the step of forming the UBM layer, further comprising forming a patterned dielectric layer over the active surface of the die, wherein the patterned dielectric layer has a plurality of openings that expose the bonding pads and the UBM layer is disposed above the patterned dielectric layer.

4. The assembling method of claim 1, wherein the step of forming the under-bump-metallurgy layer includes:
forming a metallic layer over the bonding pads; and
patterning the metallic layer to form the under-bump-metallurgy layer over the bonding pads.

5. The assembling method of claim 4, wherein the step of forming the metallic layer includes one selected from the group consisting of electroplating, sputtering, and evaporation.

6. The assembling method of claim 4, wherein the metallic layer is a composite metallic layer.

7. The assembling method of claim 1, wherein the under-bump-metallurgy layer is a composite metallic layer.

8. The assembling method of claim 1, wherein the step of bonding the terminal electrodes of the passive component to the solder block includes positioning the terminal electrodes in contact with the solder block and performing a reflow operation so that the solder block is melted and bonded with the terminal electrodes.

9. A chip structure, comprising:
a die having an active surface and a back surface, wherein the active surface is implemented with a plurality of bonding pads;
an under-bump-metallurgy layer disposed over the bonding pads;
a plurality of solder blocks respectively disposed above the under-bump-metallurgy layer; and
a passive component having a plurality of terminal electrodes, which are respectively coupled to the UBM layer through the solder blocks.

10. The chip structure of claim 9, further comprising a patterned dielectric layer over the active surface of the die, wherein the patterned dielectric layer has a plurality of openings that expose the bonding pads and the UBM layer is disposed above the patterned dielectric layer.

11. The chip structure of claim 9, wherein the UBM layer further comprises a re-distribution layer and the redistribution layer is electrically connected to the bonding pads.

12. The chip structure of claim 9, wherein the under-bump-metallurgy layer is a composite metallic layer.

13. A chip package structure, at least comprising:
a substrate having an upper surface;
a die having an active surface and a back surface, wherein the back surface of the die is in contact with the upper surface of the substrate and the active surface is implemented with a plurality of bonding pads;
an under-bump-metallurgy layer disposed over the bonding pads;
a solder block disposed on the under-bump-metallurgy layer;
a passive component with a plurality of terminal electrodes, wherein the terminal electrodes are coupled to the under-bump-metallurgy layer through the solder block;
a plurality of conductive wires electrically connecting the die and the substrate; and
a packaging plastic enclosing the die, the passive component, and the conductive wires.

14. The chip package structure of claim 13, wherein the UBM layer further comprises a re-distribution layer and the re-distribution layer is electrically connected to the bonding pads.

15. The chip package structure of claim 13, wherein the under-bump-metallurgy layer is a composite metallic layer.

16. The chip package structure of claim 13, further comprising a patterned dielectric layer disposed over the active surface of the die with a plurality of openings to expose the bond pads and the UBM layer is disposed above the patterned dielectric layer.
